(19) United States
(12) Patent Application Publication
(10) Pub. No.: US 2026/0144142 A1
(43) Pub. Date: May 21, 2026

(54) Thermal Test Chips and Assemblies

(71) Applicant: Thermal Engineering Associates, Inc., Santa Clara, CA (US)

(72) Inventors: Dongkai Shangguan, Campbell, CA (US); Bernard S. Siegal, Menlo Park, CA (US)

(21) Appl. No.: 18/952,183

(22) Filed: Nov. 19, 2024

(51) Int. Cl. H01L 25/065; G01R 31/28; H01L 23/42; H01L 23/48; H05K 1/02

(52) U.S. Cl. CPC H10W 90/00; G01R 31/2884; H05K 1/0203; H05K 1/0272; H10W 20/20; H10W 40/70; H05K 2201/10734; H10W 90/284; H10W 90/288

(57) ABSTRACT

A thermal test chip assembly includes a printer wiring board or substrate, a vertical stack of thermal test chips and optionally functional chips, and an interconnection means between the chips and the wiring board. A thermal test chip with non-uniform thickness includes a semiconductor substrate, and at least one resistor and at least one diode fabricated on the substrate. Variable non-uniform thicknesses and material deletion regions are employed to emulate the thermal characteristics of a stacked die configuration. Unit cells enable thermal test chips of predetermined size and power arrayed in m x n combinations. Thermal assemblies including vertical die stacks are emulated, and thermal test sets including support equipment are disclosed.

### RELATED APPLICATIONS

This application claims the benefit of priority of U.S. Provisional Ser. No. 63/721,164, filed on Nov. 15, 2024 by the same inventors, which is incorporated herein by reference in its entirety.

### BACKGROUND

### Field of the Invention

This invention relates generally to thermal test chips. More particularly, this invention relates to thermal test chip assemblies that emulate vertical stacks of functional die.

### Background Art

Thermal management is an ever more critical challenge for semiconductor devices, as their functional density and power density increase. Packages comprising stacked die exhibit increased thermal resistance, and they are particularly difficult to analyze and ratify. Rising junction temperatures can adversely affect both the performance and the reliability of semiconductor devices. Accordingly, effective tools and test methodologies are needed to support the development of effective thermal management solutions. Thermal Test Chips (TTCs) are a critical enabler.

### SUMMARY

Embodiments of the present disclosure are useful because they can accurately emulate stacked die configurations, thereby enabling concurrent development of thermal management solutions before the real functional chips become available. This is critical for the rapid development of semiconductor devices, especially three-dimensional (3D) stacks of chips, as both the development of the chips and the development of the required thermal management solutions take considerable time (often longer than a year), and concurrent development is highly desirable. Furthermore, embodiments of the present invention are useful because they provide an objective, technology/manufacturer agnostic platform for characterizing various thermal management solutions (e.g., thermal interface material, heat sink, and so on), thereby enabling the rapid development of innovative solutions, which are intended for a variety of end applications.

Various example embodiments disclose thermal test chip assemblies comprising a vertical stack of thermal test chips having interconnection means between test chips and a wiring substrate. Other embodiments include unit cells, unit cell arrays comprising m x n unit cells, where m and n are integers, and thermal test sets comprising thermal test chips and support equipment such as power supplies, heat sinking assemblies or equipment, and testers.

In another example embodiment, a stacked or non-uniform thickness thermal test chip comprises at least one resistor and at least one diode fabricated on a semiconductor substrate. The substrate may comprise silicon (Si), germanium (Ge), gallium nitride (GaN), gallium arsenide (GaAs), indium phosphide (InP), or silicon carbide (SiC), as non-limiting examples. The test chips may comprise variable non-uniform thicknesses for emulating the thermal characteristics of proposed 3D stacked die configurations comprising functional die. Gaps in the profile of a thermal test chip may be described as material deletion regions. The gaps may be filled with air, a cooling fluid, or with gap fill materials including, but not limited to, oxides, epoxy, or materials that aid in a planarization process applied to one or more chips.

An example thermal test chip assembly includes a printed wiring board or substrate, a stack of chips, and interconnection means. The stack of chips can be a vertical stack and can include a plurality of thermal test chips and optionally one or more functional chips. The interconnection means provides connection between contact pads of a thermal test chip or a functional chip and corresponding contact pads of the printed wiring board or substrate. The interconnection means can include solder bumps, solder balls, metal pillars, microbumps, direct metal-to-metal bonding, through silicon vias (TSVs), wire bonds, or any combination thereof. The areas surrounding the solder bumps, metal pillars, or microbumps can be filled with underfill or organic or inorganic dielectric materials. Pairs of test chips within the vertical stack can be interconnected face-to-face, face-to-back, or back-to-back.

An example thermal test chip assembly can additionally include a die attach material disposed between a pair of thermal test chips in the vertical stack or between a thermal test chip and a substrate. The die attach material can include, for example, epoxy based or other adhesives, a metal or alloy, or a composite material, in various forms.

In an example thermal test chip assembly, the substrate can be an organic substrate, a silicon substrate, a ceramic or glass substrate, a composite material, or a package cavity surface.

An example thermal test chip assembly can additionally include a thermal interface material (TIM) and a cooling element (or a heat dispersing element or a heat sinking assembly) coupled with the thermal interface material. The thermal interface material can include a solid or liquid metal or alloy, a graphene material, a graphite material, a gel or grease, diamond, or a composite material. Alternatively or additionally, the thermal test chip assembly can include channels on the backside of the chip for cooling fluids.

In an example thermal test chip assembly the substrate can be attached to a printed wiring board using solder balls. At least one terminal can be disposed on the printed wiring board or substrate for connecting with instrumentation.

In example thermal test chip assemblies, gaps between the chips can be filled with cooling solutions or gap fill materials such as oxides, epoxy, or other type of semiconductor molding compound.

An example thermal test chip includes a semiconductor substrate, at least one resistor, and at least one diode. The resistor(s) and diodes(s) are fabricated on the substrate, and can function as heating and thermal sensing elements. The thermal test chip can have varying thicknesses to emulate the thermal characteristics of a stacked die configuration. That is, the thermal test chip can have different thicknesses at different locations on the chip.

In the example thermal test chip, the resistor(s) and diode(s) are contained within a unit cell that is repeatable in each of two dimensions to create customizable arrays of unit cells. Dicing streets between unit cells facilitate dicing the wafer into individual chips. The semiconductor substrate can be silicon (Si), germanium (Ge), gallium arsenide (GaAs), gallium nitride (GaN), indium phosphide (InP), silicon carbide (SiC), or any other suitable semiconductor material. The individual ones of the resistor(s) and diode(s) are addressable/accessible via contact pads of the thermal test chip.

The example thermal test chips can optionally include redistribution layers (RDLs) on at least one face of the test chip. The redistribution layers can include alternate layers of conducting material and dielectric material. The example thermal test chips can additionally include terminals or connectors comprising solder bumps, microbumps, copper pillars, or metal pads for direct metal-to-metal bonding, or metal pads for wire bonding.

The example thermal test chips can optionally include areas for fabricating TSV's, without interfering with the other elements or functions of the chip.

In example thermal test chips, power distribution between resistors in a unit cell or between unit cells can be adjusted to emulate a hot spot. The unit cells can be configured to emulate chips of different dimensions and power distributions, and selected unit cells can be interconnected within the chip. The example chips can have an adjustable thickness, the adjustable thickness varied across the chip to correspond with the total thickness of one or more stacked die elements at specific locations. The adjustable thickness can be achieved, for example, by material deletion regions. Material deletion regions can be microchannels on the backside of the chip, which can be filled with cooling solutions for thermal management. Optionally, the material deletion regions can be filled with air, gap fill materials such as epoxy or oxides, or materials that aid in the planarization process of the chips.

An example thermal test set includes a thermal test vehicle and a thermal test chip. The thermal test vehicle can include a wiring substrate, and the thermal test chip can be mounted on the wiring substrate. A cooling or heat sinking assembly can be coupled with the thermal test chip. Support equipment can include at least one of a power supply and a tester.

Another example thermal test chip assembly includes a first semiconductor substrate, a second semiconductor substrate, and a circuit substrate. The first semiconductor substrate includes a first surface, a second surface opposite the first surface, and a first set of integrated circuits formed in and on the second surface of the first semiconductor substrate. The first set of integrated circuits can include a first plurality of thermal test circuits. The second semiconductor substrate includes a first surface, a second surface opposite the first surface, and a second set of integrated circuits formed in and on the second surface of the second semiconductor substrate. The circuit substrate can include a first set of electrical contacts and interconnect circuitry electrically coupling the first set of integrated circuits and the second set of integrated circuits to the first set of electrical contacts. The second set of integrated circuits can include functional circuitry of an electronic device being emulated. Alternatively, the second set of integrated circuits can include a second plurality of thermal test circuits. As another option, the second semiconductor substrate can be a blank chip, or “dummy” chip, with no integrated circuits.

In an example thermal test chip assembly, the first semiconductor substrate, the second semiconductor substrate, and the circuit substrate can be coupled in a stacked relationship. The first semiconductor substrate can be disposed between the second semiconductor substrate and the circuit substrate, and the first surface (e.g., the bottom) of the first semiconductor substrate can face the circuit substrate. The first surface (e.g. bottom) of the second semiconductor substrate can face the second surface (e.g., top) of the first semiconductor substrate. The second set of integrated circuits can include a plurality of contact pads formed on the second surface of the second semiconductor substrate. Each contact pad of the contact pads formed on the second surface of the second semiconductor substrate can be coupled to the interconnect circuitry of the circuit substrate via a wire. Alternatively, the first semiconductor substrate can include a first set of TSVs, and the second semiconductor substrate can include a second set of TSVs. The first set of integrated circuits can be coupled to the interconnect circuitry of the circuit substrate by some of the TSVs of the first set of TSVs, and the second set of integrated circuits can be coupled to the interconnect circuitry of the circuit substrate by the second set of TSVs and other TSVs of the first set of the TSVs.

In another example thermal test chip assembly, the first semiconductor substrate, the second semiconductor substrate, and the circuit substrate can be coupled in a stacked relationship. The first semiconductor substrate can be disposed between the second semiconductor substrate and the circuit substrate. The second surface (e.g., top) of the first semiconductor substrate can face the second surface (e.g., top) of the second semiconductor substrate. The example thermal test chip assembly can additionally include an interconnect layer disposed between the first semiconductor substrate and the second semiconductor substrate. The interconnect layer can electrically couple the second set of integrated circuits to the interconnect circuitry of the circuit substrate.

Optionally, the first semiconductor substrate can include a first set of TSVs and a second set of TSVs. The first set of integrated circuits can be electrically coupled to the interconnect circuitry of the circuit substrate by the first set of TSVs, and the second set of integrated circuits can be electrically coupled to the interconnect circuitry of the circuit substrate by the second set of TSVs.

In another example thermal test chip assembly, the first semiconductor substrate, the second semiconductor substrate, and the circuit substrate are coupled in a stacked relationship. The first semiconductor substrate is disposed between the second semiconductor substrate and the circuit substrate. The second surface (e.g., top) of the first semiconductor substrate faces the circuit substrate. The first set of semiconductor circuits includes a second set of electrical contacts, and contacts of the second set of electrical contacts are electrically coupled to interconnect circuitry of the circuit substrate. Contacts of the second set of electrical contacts can be directly bonded to the interconnect circuitry of the circuit substrate. Alternatively, the thermal test chip assembly can additionally include an interconnect layer disposed between the first semiconductor substrate and the circuit substrate, and the interconnect layer can electrically couple the first set of contacts to the second set of contacts.

In a particular example thermal test chip assembly, the second surface (e.g., top) of the second semiconductor substrate faces the first surface (e.g., bottom) of the first semiconductor substrate. The first semiconductor substrate can include a first set of TSVs. The first set of integrated circuits can be electrically coupled to the second set of integrated circuits by the first set of TSVs.

Another example thermal test chip assembly can additionally include a third semiconductor substrate. The third semiconductor substrate has a first surface, a second surface opposite the first surface, and a third set of integrated circuits formed in and on the second surface of the third semiconductor substrate. The third set of integrated circuits can be electrically coupled to the interconnect circuitry of the circuit substrate. The second set of integrated circuits can include a second plurality of thermal test circuits. The first semiconductor substrate can be disposed between the circuit substrate and the second semiconductor substrate, and the first semiconductor substrate can be disposed between the circuit substrate and the third semiconductor substrate.

The second and third semiconductor substrates can be stacked on one another or adjacent one another on the first semiconductor substrate. In the stacked configuration, the second semiconductor substrate is disposed between the first semiconductor substrate and the third semiconductor substrate. In the adjacent configuration, the second semiconductor substrate is disposed over a first area of the first semiconductor substrate, and the third semiconductor substrate is disposed over a second area of the first semiconductor substrate. The first area is spaced apart from the second area.

The third set of integrated circuits can include functional circuitry of an electronic device being emulated, a third plurality of thermal test circuits, or some combination thereof. Alternatively, the third semiconductor substrate can be a non-functional, “dummy” chip.

In another example thermal test chip assembly, the first surface (e.g., the bottom) of the first semiconductor substrate faces the circuit substrate. The second surface (e.g., the top) of the second semiconductor substrate faces the second surface (e.g., the top) of the first semiconductor substrate. The second surface (e.g., the top) of the third semiconductor substrate also faces the second surface (e.g., the top) of the first semiconductor substrate. The first semiconductor device can include a first set of TSVs, a second set of TSVs, and a third set of TSVs. The first set of integrated circuits can be electrically connected to the interconnect circuitry of the circuit substrate by the first set of TSVs. The second set of integrated circuits can be electrically connected to the interconnect circuitry of the circuit substrate by the second set of TSVs, and the third set of integrated circuits can be electrically connected to the interconnect circuitry of the circuit substrate by the third set of TSVs.

The example thermal test chip assembly can additionally include a first interconnect layer and a second interconnect layer. The first interconnect layer can be disposed between the first semiconductor substrate and the second semiconductor substrate. So disposed, the first interconnect layer electrically can connect the second set of integrated circuits to the second set of TSVs. The second interconnect layer can be disposed between the first semiconductor substrate and the third semiconductor substrate. So disposed, the second interconnect layer can electrically connect the third set of integrated circuits to the third set of TSVs.

Optionally, the example thermal test chip assemblies can include a “dummy chip.” For example, the third semiconductor substrate can have a first surface and a second surface opposite the first surface. The third semiconductor substrate can be mechanically coupled to the first semiconductor substrate and the second semiconductor substrate, but there are no electrical connections between the first set of integrated circuits and any integrated circuits of the third semiconductor substrate. Similarly, there are no electrical connections between the second set of integrated circuits and any integrated circuits of the third semiconductor substrate. In a particular example thermal test chip assembly, the third semiconductor substrate is a dummy chip with no operational circuits. Thus, the dummy chip can be a chip that has circuits (e.g., a scrap chip), but the circuits are not connected. Or the dummy chip can be simply a chip (e.g., a chip of a diced wafer) with no circuits even formed in the chip.

An example thermal test chip is also disclosed and includes a semiconductor substrate. The semiconductor substrate has a first surface, a second surface opposite the first surface, and an array of thermal test circuits formed in an on the second surface. The semiconductor substrate has a first thickness defined as a shortest distance between the first surface and the second surface in a first region of the semiconductor substrate. The semiconductor substrate has a second thickness defined as a shortest distance between the first surface and the second surface in a second region of the semiconductor substrate. The first thickness is greater than the second thickness.

An example method of fabricating a thermal test chip is also disclosed. The example method includes providing a semiconductor substrate having a first surface and a second surface opposite the first surface. The example method additionally includes forming an array of thermal test circuits in and on the second surface of semiconductor substrate. The example method additionally includes removing material from a predefined region of the first surface of the semiconductor substrate. By removing the material, a first thickness of the semiconductor substrate in the predefined region of the first surface is less than a second thickness of the semiconductor substrate in a second region outside of the predefined region.

### BRIEF DESCRIPTION OF THE DRAWINGS

The present invention is described with reference to the following drawings, wherein like reference numbers denote substantially similar elements:

FIG. 1 illustrates an example semiconductor wafer populated with unit cells configured for thermal analysis;

FIG. 2 illustrates in a plan view and a schematic view a thermal test chip (TTC) comprising resistors and diodes in an example unit cell configuration;

FIG. 3 illustrates in a plan view and a schematic view a TTC comprising resistors and a diode in an alternative unit cell configuration;

FIG. 4 illustrates in a plan view an example 2×2 unit cell array;

FIG. 5 illustrates in cross-section an example assembly of a single TTC mounted on a wiring substrate, which is mounted on a printed wiring board (PWB) or printed circuit board (PCB);

FIG. 6 illustrates in cross-section a monolithic assembly of a variable-thickness, thermally configured TTC mounted on a wiring substrate;

FIG. 7 illustrates in cross-section an assembly comprising a vertical stack of TTCs mounted on a wiring substrate, including wire bond connections;

FIG. 8 illustrates in cross-section an assembly comprising a vertical stack of TTCs in a face-to-face arrangement mounted on a wiring substrate and connected using through silicon vias (TSVs);

FIG. 9 illustrates in cross-section an assembly comprising a vertical stack of TTCs in a face-to-face arrangement mounted on a wiring substrate and connected via a wire bond connection;

FIG. 10 illustrates in cross-section an assembly comprising a vertical stack of TTCs in a face-to-back arrangement mounted on a wiring substrate and connected with silicon vias (TSVs); and

FIG. 11a illustrates an example thermal test vehicle for a thermal test chip assembly;

FIG. 11b illustrates another example thermal test vehicle for a thermal test chip assembly;

FIG. 11c illustrates another example thermal test vehicle for a thermal test chip assembly;

FIG. 11d illustrates another example thermal test vehicle for a thermal test chip assembly; and

FIG. 11e illustrates another example thermal test vehicle for a thermal test chip assembly.

### DETAILED DESCRIPTION

Thermal test chips (TTCs) enable concurrent development of thermal management solutions before the real functional chip or stack of chips becomes available. They support both steady state and transient thermal characterization of an intended semiconductor package. Available thermal test sets may also enable the characterization of heat sinks, heat spreaders/dispersers, cooling solutions, vapor chambers, fans, heat pipes, cold plates, die attach films (DAFs), thermal interface materials (TIMs), and the like. Accordingly, TTCs enable the assessment of the thermal reliability risks and the effectiveness of the thermal management solutions for a semiconductor chip or device, including stacked die arrangements. The TTCs also support power and/or temperature mapping for proposed thermal management designs, as well as validation and calibration of thermal simulation models. Such capabilities are critical for the rapid development of semiconductor technologies. As described herein, the TTCs precisely model and represent the power input and power density distribution of each proposed chip (typically non-uniform), and simultaneously accurately sense the temperature distribution (using integrated sensors) over the entire die in real time, limited only by small spaces between the heating elements and between the sensing elements. Furthermore, the TTCs are configurable to physically represent many alternative stacked and/or variable thickness packaging structures, as required to represent the intended packaging structures, including vertical stacks of chips for example. Vertically stacked TTC's can also be used to increase the power density (i.e., power per unit area) beyond the maximum power density of a single TTC.

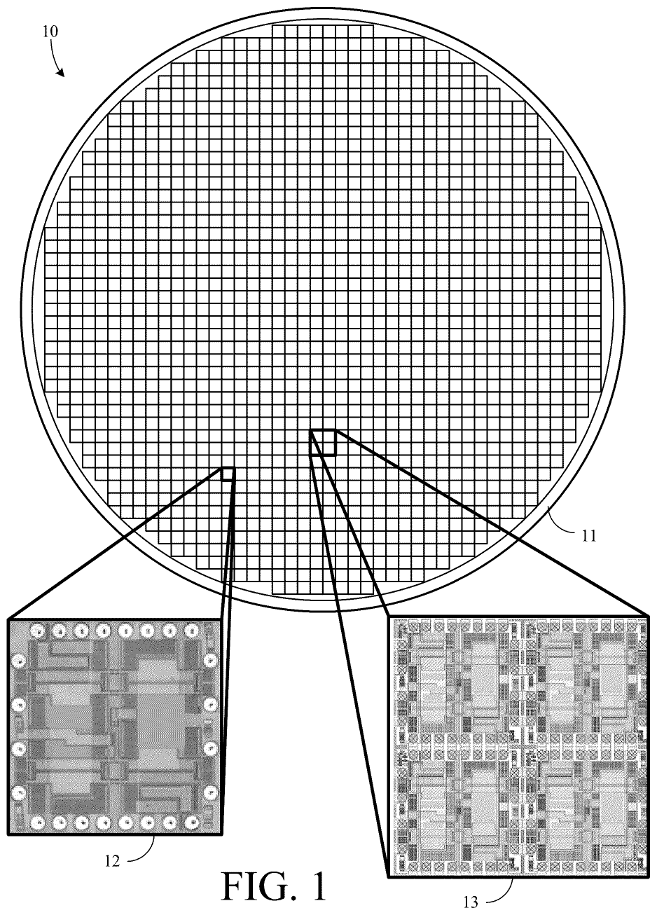

FIG. 1 illustrates a plan view 10 of a semiconductor wafer 11. Wafer 11 can be of any conventional size, such as 6, 8 or 12 inch diameter, or other diameter, depending on the wafer material and other considerations. Wafer 11 is arrayed with unit cells 12 in an example embodiment of the present disclosure. The unit cells may be identical to one another or mirror images of one another. Each unit cell 12 includes at least one resistor and at least one diode. By choosing various paths for dicing wafer 11, m×n unit cell arrays may be selectively produced, where m and n are integers that may vary between 1 and 100 for example. Accordingly, a thermal test chip of almost any overall size or form factor can be closely replicated. A 2×2 unit cell array 13 is shown. Each thermal test chip has an active side where transistors, resistors, and/or diodes are formed, and a back side, which may be referred to as an inactive side. Optionally, a TTC can have both sides active. That is, a chip can have thermal test circuitry formed in and on both the front side and the back side of the chip.

As a non-limiting example embodiment of the present disclosure, a unit cell comprises resistor elements and at least one diode. A substrate wafer comprises a semiconductor material such as silicon. A diode well is used to produce a temperature sensing diode with a short response time (for example, less than 1 μsec). An interconnect can comprise metal and dielectric layers. Metal film resistors can comprise titanium nitride, tantalum nitride, or some other similar materials, with a stable low temperature coefficient below 20 ppm/° C., which results in well controlled power distribution and heat dissipation across a die area that may include hot spots for example. Alternative embodiments may employ other resistor compositions and configurations. Power delivery to individual resistors may be adjusted to emulate hot spots. A top dielectric can be a passivation layer of silicon nitride. Alternative embodiments may employ other passivation compositions and configurations.

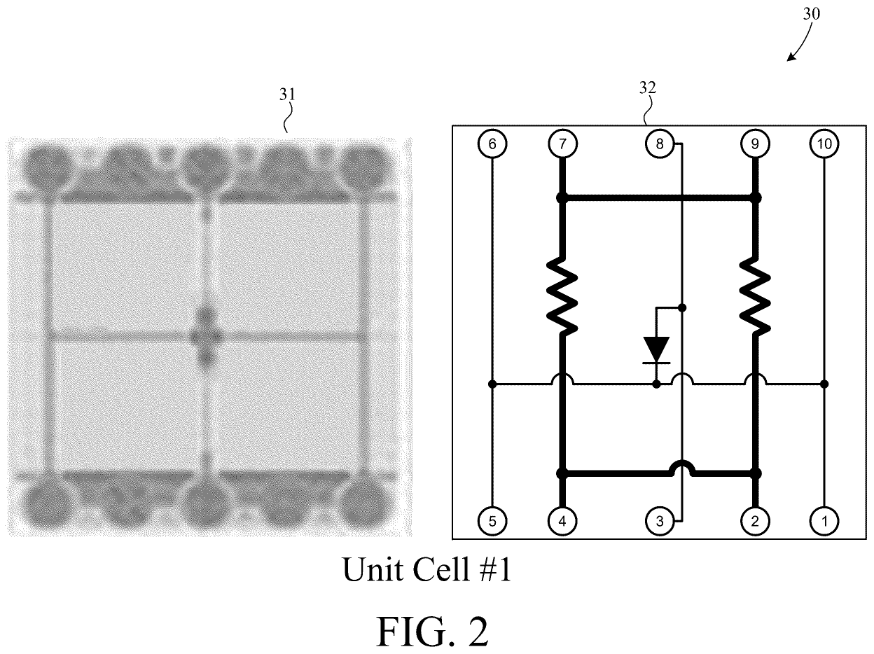

FIG. 2 illustrates a side-by-side view 30, including a plan view 31 and a schematic view 32 of a small unit cell of example embodiments of the present disclosure. The example cell is sized 1 mm×1 mm, providing a fine size increment for unit cell arrays comprising this design. The area of resistive material comprises above 60% of the die area in some example embodiments of the present disclosure.

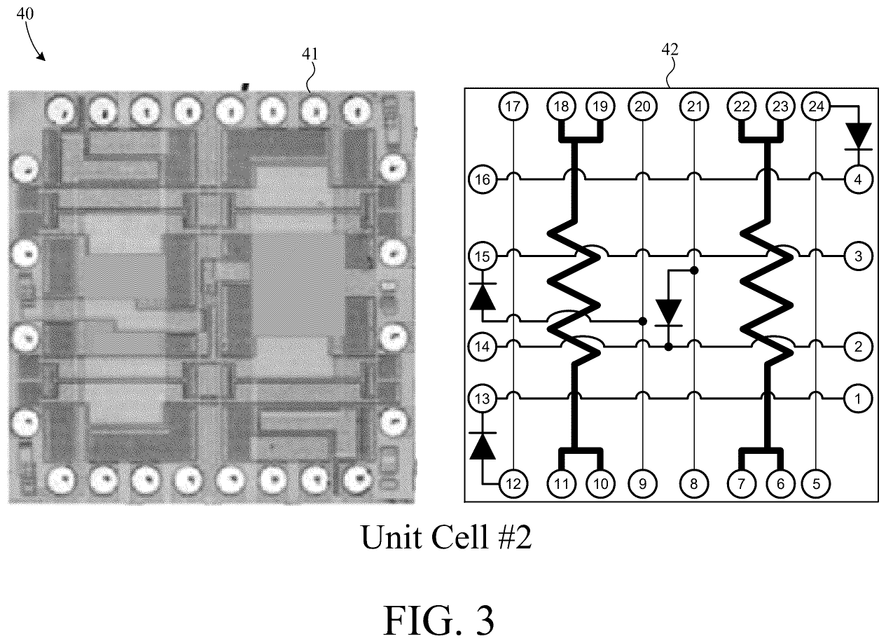

FIG. 3 illustrates a side-by-side view 40, including a plan view 41 and a schematic view 42 of a large unit cell (2.54 mm×2.54 mm) of example embodiments of the present disclosure. The area of resistive material comprises above 85% of the die area in some example embodiments of the present disclosure. Schematic view 42 shows that the anode of the central diode can be addressed using pins 8 and 21; the cathode can be addressed using pins 2 and 14. This configuration enables the diode to be driven using pins 8 and 2 for example, while being sensed (read) using pins 21 and 14. These 4-wire Kelvin connections may be used for improved measurement accuracy, by removing voltage drops associated with the connections such as wiring and on-chip trace resistances in the driving connection. Similarly, the resistor on the left side can be driven using pins 11 and 18 and sensed using pins 10 and 19. This ability to uniquely address a particular diode or resistor is available in unit cell arrays if “straight through” address lines are interconnected to provide a unique (x, y) address for each element in the unit cell array; these “straight through” interconnections can be provided on the wiring substrate to which the unit cell array is mounted.

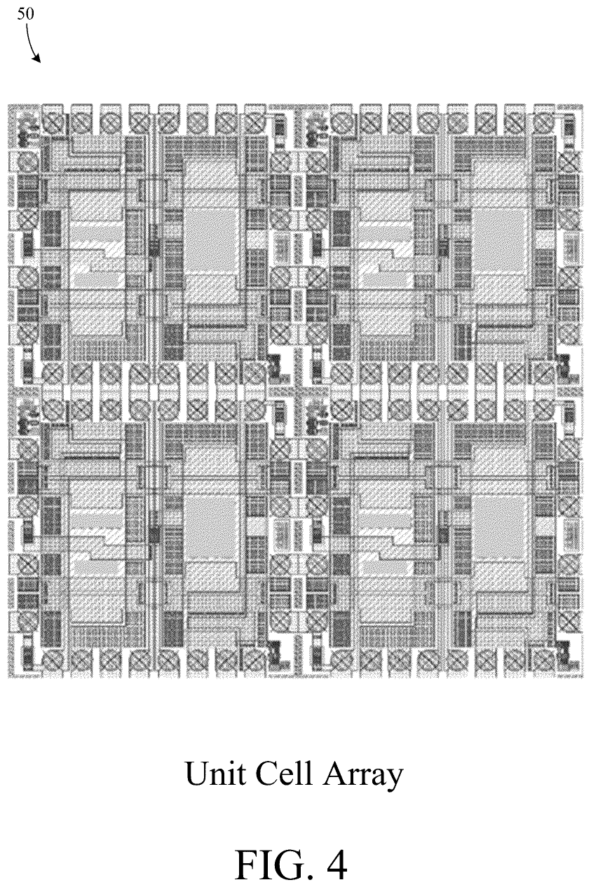

FIG. 4 illustrates a plan view 50 of a 2×2 unit cell array comprising four large unit cells of example embodiments of the present disclosure. If an n×m array is sized at 10×10, the result is a 1-inch square chip, big enough to emulate large size semiconductor chips, with the array including high power resistors that are capable of emulating high power chips.

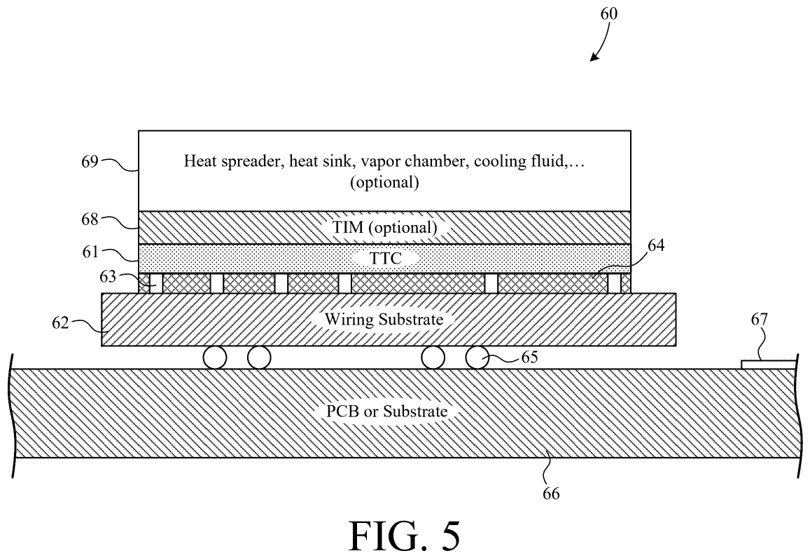

FIG. 5 illustrates a cross-sectional view 60 of a thermal test chip 61 mounted on a wiring substrate 62 using microbumps 63, which is then mounted on a PCB 66 using solder balls 65, in an example embodiment of the present disclosure. Microbumps 63 may be replaced with other kinds of terminals or connectors, including, but not limited to, solder balls, copper pillars, direct metal-to-metal bonds, and so on. In this example embodiment, TTC 61 is in a face-down orientation, with an integrated circuitry layer of TTC 61 facing the top surface of wiring substrate 62. Wiring substrate 62 may comprise a printed wiring board (PWB), an organic substrate, a ceramic substrate (including glass), a silicon substrate, a composite material, or package cavity surface, as non-limiting examples. Optionally, spaces around the interconnect bumps may be filled with underfill 64, which can be organic or inorganic dielectric materials to enhance reliability. As another example, the underfill material may be an epoxy with fillers. The exact material of underfill 64 can be selected based on thermal mechanical properties of particular functional chips being emulated. An optional thermal interface material (TIM) 68 may couple the thermal test chip 61 with a heat-sinking assembly 69. The heat sinking assembly 69 may comprise a heat sink, a fan, a heat spreader, a vapor chamber, a chamber containing cooling fluid, or any combination thereof. A contact pad 67 on PCB 66 is provided as a terminal for connecting to instrumentation, using wire connections or connectors. Alternatively, such contact pad 67 may be provided on the wiring substrate 62. The instrumentation may include a power supply, a current source, and a voltage measurement module, as non-limiting examples.

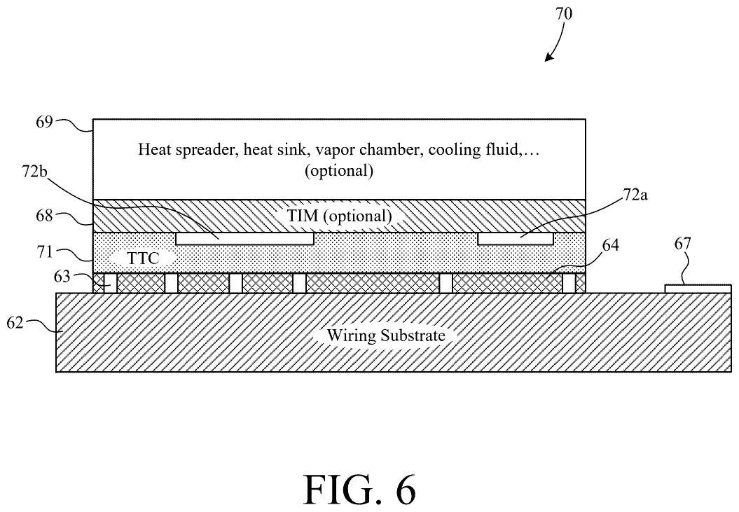

FIG. 6 illustrates a cross-sectional view 70 of a thermal test chip 71 having different thicknesses at different locations, according to another example embodiment of the present disclosure. In this embodiment, thermal test chip 71 models or emulates a stacked die arrangement. TTC 71 includes material deletion regions such as 72a, 72b, that are filled with air or other materials (such as cooling solutions, gap fill materials such as oxides, epoxy, materials that assist in the planarization process of the die, and so on). A material deletion region such as 72a may be created using a dicing saw in a particularly cost-effective example embodiment. Other methods, such as etching, abrading, and so on, may also be used. The size (including area and depth) and placement of material deletion regions such as 72a are predetermined by the structure of a die or stacked die arrangements to be modeled or emulated, including gaps between the die, such that the finished structure emulates the overall thermal structure of the stacked dies. The various regions of the die 71 may be at different thicknesses, such that the top of the die (back side of the chip) may be at various heights at different locations. In this particular example embodiment, TTC 71 is oriented face down, with an integrated circuitry layer of TTC 71 facing the top surface of wiring substrate 62. Thickness variations may be created using saw cuts of varying width and depth. Alternatively, thickness variations can be created by patterning the back side of the die and etching off the material in the exposed area with a wet etch or dry etch process. The power density distribution of thermal test chip 71 can be configured to simulate the power density distribution of stacked dies. Optionally, spaces around the interconnect bumps 63 may be filled with underfill 64, which can be organic or inorganic dielectric materials, or any other suitable material. As previously described, TIM 68, heat sinking assembly 69, and connector 67 may be included in the test setup. In an embodiment of the present disclosure, the material deletion regions such as 72a, 72b, are microchannels on the backside of the chip which are filled with cooling solutions for thermal management.

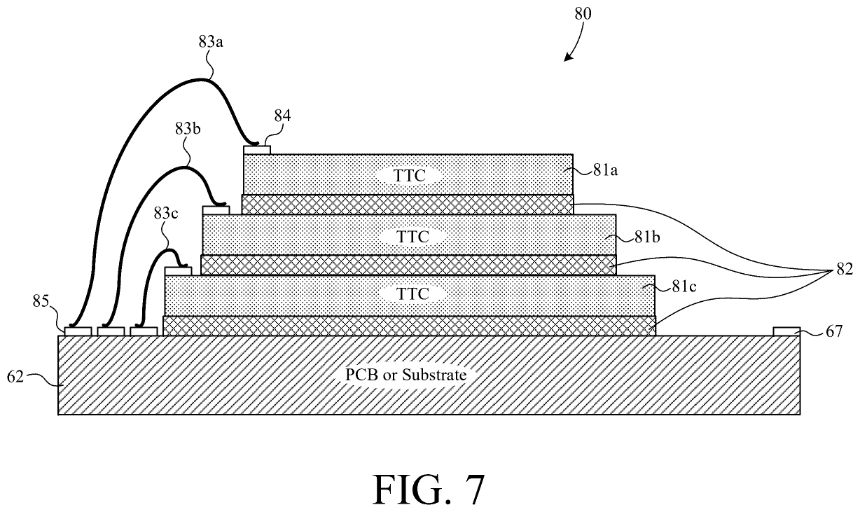

FIG. 7 illustrates a cross-sectional view 80 of a stacked assembly of thermal test chips 81a, 81b, 81c, according to another example embodiment of the present disclosure. Thermal test chips 81a, 81b, 81c are arranged in a vertical stack as shown, with die attach materials (films, adhesives, or metallic alloys, which can be a metal or alloy, or a composite material, for example) 82 used to couple between pairs of chips in the stack and between the base chip 81c and the wiring substrate 62. The thermal test chips may be arranged differently. For example, a larger chip may be disposed above a smaller chip, one chip may overhang the edge of another chip, and so on. As shown, each of thermal test chips 81a, 81b, 81c is in a face up orientation. That is, the surface of each of thermal test chips 81a, 81b, 81c including the integrated circuitry is on the top of the respective chip in the view of FIG. 7. Bonding wires 83a, 83b, 83c are used to connect between contact pads such as 85 on wiring substrate 62 and corresponding contact pads such as 84 on thermal test chip 81 a. Alternatively, bonding wires may connect between one of thermal test chips 81a, 81b, 81c and another of thermal test chips 81a, 81b, 81c. As previously described, connector 67 may be used in the test setup.

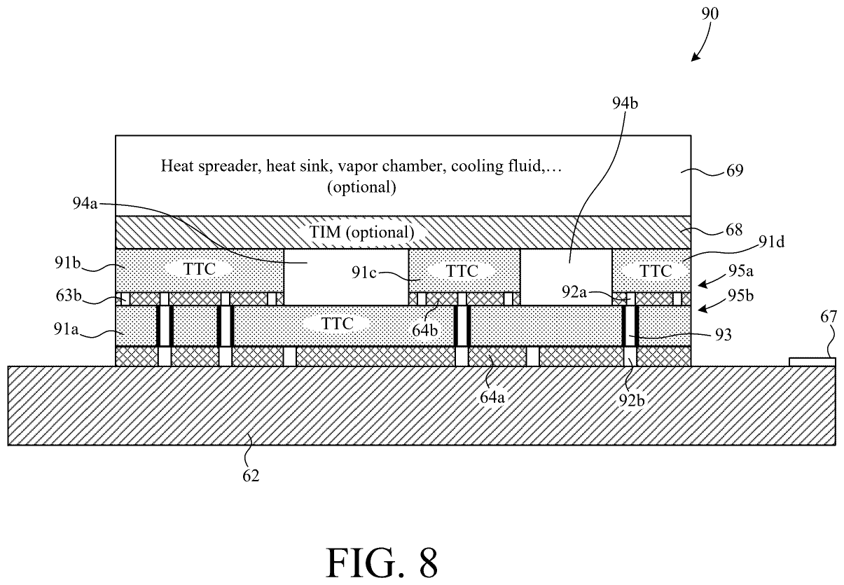

FIG. 8 illustrates a cross-sectional view 90 of a stacked assembly of thermal test chips, according to another example embodiment of the present disclosure. Thermal test chips 91a, 91b, 91c, and 91d are arranged to emulate a desired thermal structure that may represent a proposed thermal structure comprising functional chips in a stacked die configuration. Gaps 94a and 94b are shown between chips in the proposed thermal structure. Gaps 94a and 94b can be filled with air, a cooling fluid, or gap fill materials such as underfill, oxides, epoxy, and/or other materials that assist in the planarization process of the die. Each thermal test chip has an active side where transistors or diodes (e.g., integrated circuitry) are formed, and a back side, sometimes referred to as the inactive side. In the figure, thermal test chips 91b, 91c, and 91d all have their active side at location 95a (i.e., face down). Thermal test chip 91a has its active side at location 95b (i.e., face up). Accordingly, this arrangement may be described as a “face-to-face” configuration. A TSV 93 connects between contact pad 92a of thermal test chip 91d and contact pad 92b of wiring substrate 62, providing an interconnection means between a contact pad of a stacked chip and a corresponding pad of wiring substrate 62, using microbumps 63 on the die for example. TSV 93 is one of a set that includes a plurality of TSVs, only four of which are shown in the view of FIG. 8. It should be understood that the actual number of TSVs required will depend on the number of contact pads of TTCs 91 a-c, between which interconnections must be made. In some embodiments, redistribution layers (RDLs) may be provided at either or both of the active side and the back side of a thermal test chip. If present, the redistribution layers (not shown) will comprise alternating layers of conductive and dielectric material, and conductive traces in the redistribution layers will connect between electrical nodes such as contact pad 92a, as in a fanout configuration. Use of one or more RDL layers makes it possible to have contact pads 92a and 92b connected through a TSV even if the two contact pads are not vertically aligned. Optionally, spaces around the interconnect bumps may be filled with underfill 64a, 64b, which can be organic or inorganic dielectric materials, or any other suitable material. As previously described, TIM 68, heat sinking assembly 69, and connector 67 may be included in the test setup.

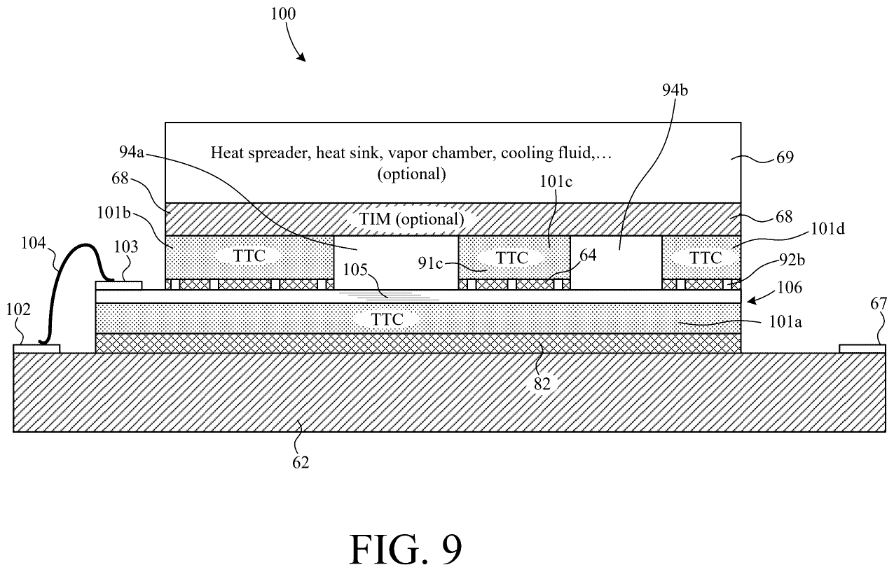

FIG. 9 illustrates a cross-sectional view 100 of a 3D assembly of thermal test chips, according to another example embodiment of the present disclosure. Thermal test chips 101a, 101b, 101c, and 101d are shown in a stacked die arrangement, wherein no TSVs are provided in the base chip 101a. Gaps 94a and 94b can be filled with air, a cooling fluid, or gap fill materials such as underfill, oxides, epoxy, and/or other materials that assist in the planarization process of the die. The interconnection means for connecting between a contact pad 102 on wiring substrate 62 and a corresponding contact pad 103 on thermal test chip 101a is provided by a bonding wire 104 (only one of many present is shown). In this case, RDLs 105 or connections between unit cells are required on the front face 106 of TTC 101a. TTC 101a is coupled with wiring substrate 62 using a die attach material (such as a film) 82. Optionally, spaces around the interconnect bumps may be filled with underfill 64, which can be organic or inorganic dielectric materials, or any other suitable material. As previously described, TIM 68, heat sinking assembly 69, and connector 67 may be included in the test setup.

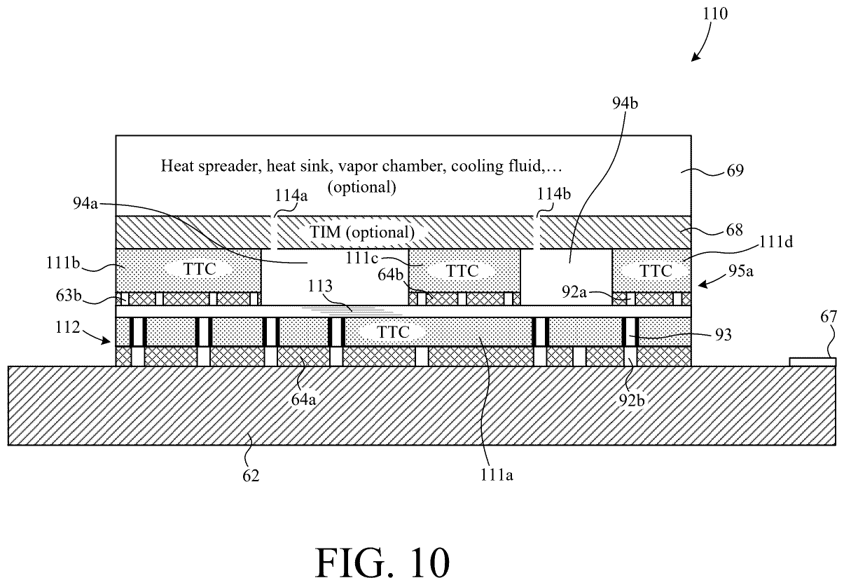

FIG. 10 illustrates a cross-sectional view 110 of a 3D assembly of thermal test chips, according to another embodiment of the present disclosure. Thermal test chips 111a, 111b, 111c, and 111d are arranged to emulate a desired thermal structure. Gap regions 94a and 94b are shown, representing gaps between chips in the proposed thermal structure. Gaps 94a and 94b can be filled with air, a cooling fluid, or gap fill materials such as underfill, oxides, epoxy, semiconductor molding compound(s), and/or other materials that assist in the planarization process of the die. In the figure, thermal test chips 111b, 111c, and 111d all have their active side at location 95a (i.e., face down). Thermal test chip 111a has its active side at location 112 (e.g., face down). Accordingly, this arrangement may be described as a “face-to-back” configuration. RDLs 113 may be used on the back face of TTC 111a, to provide electrical contacts at desired locations, to facilitate the electrical interconnection of TTCs 111b, 111c, and 111d to TTC 111a (and among TTCs 111b, 111c, and 111d). A TSV 93 connects between a contact point 92a fabricated on thermal test chip 111d and contact pad 92b, providing an interconnection means between a contact pad of a stacked chip and a corresponding pad of printed wiring board 62, using microbumps 63 on the die for example. In different embodiments, redistribution layers (RDLs) may be provided at either or both of the active side and the back side of a thermal test chip. If present, the redistribution layers will connect between electrical nodes. Optionally, spaces around the interconnect bumps may be filled with underfill 64a, 64b, which may be organic or inorganic dielectric materials, or any other suitable material. As previously described, TIM 68, heat sinking assembly 69, and connector 67 may be included in the test setup.

Gap regions 94a and 94b form a fluid conduit, through which a cooling fluid from heat sink assembly 69 can flow. The cooling fluid can be injected into gap regions 94a and 94b via a passageway 114a, formed through TIM 68, and return from gap regions 94a and 94b via a second passageway 114b. In embodiments where optional TIM 68 is omitted, heat sink assembly 69 will form the top wall of the fluid conduit, and the cooling fluid can be injected directly into and withdrawn from gap regions 94a and 94b. Although not explicitly shown, it should be understood that the circulation of a cooling fluid in gap regions 94a and 94b can also be implemented in the embodiments of FIGS. 8 and 9.

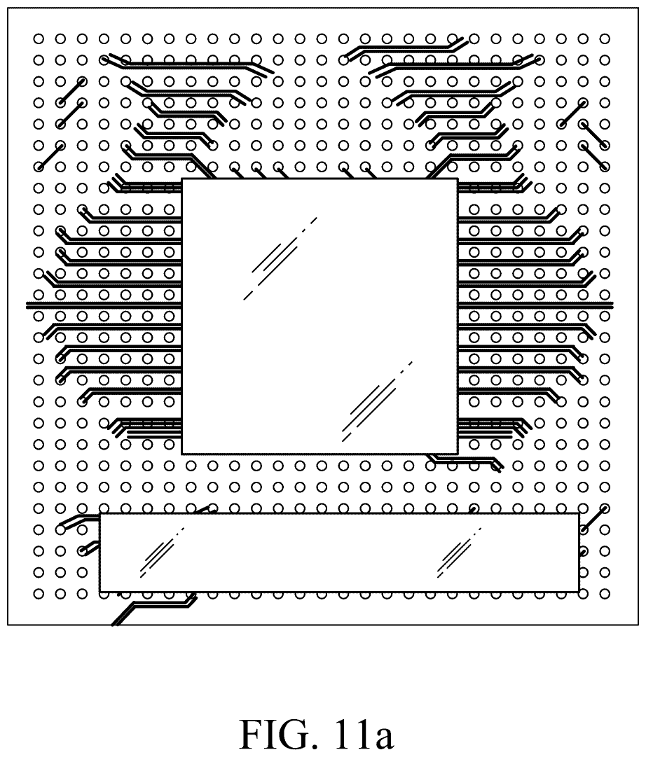

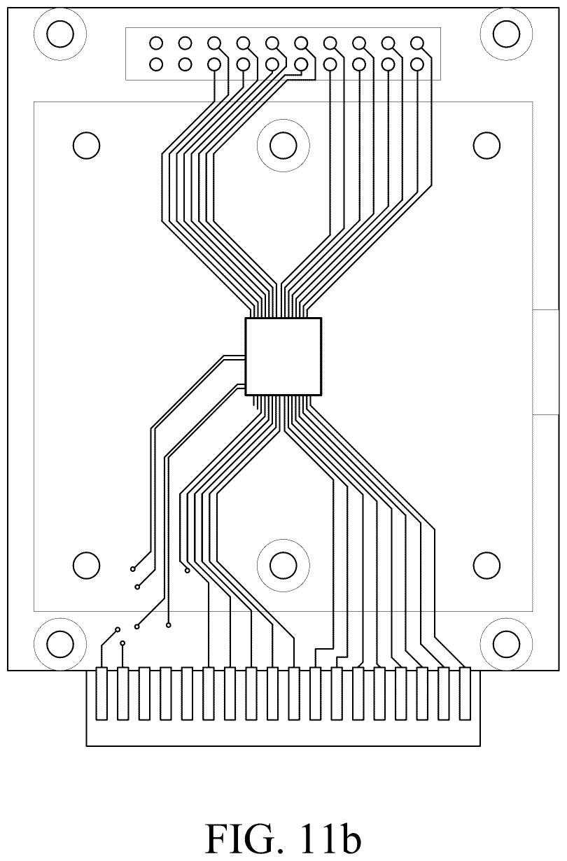

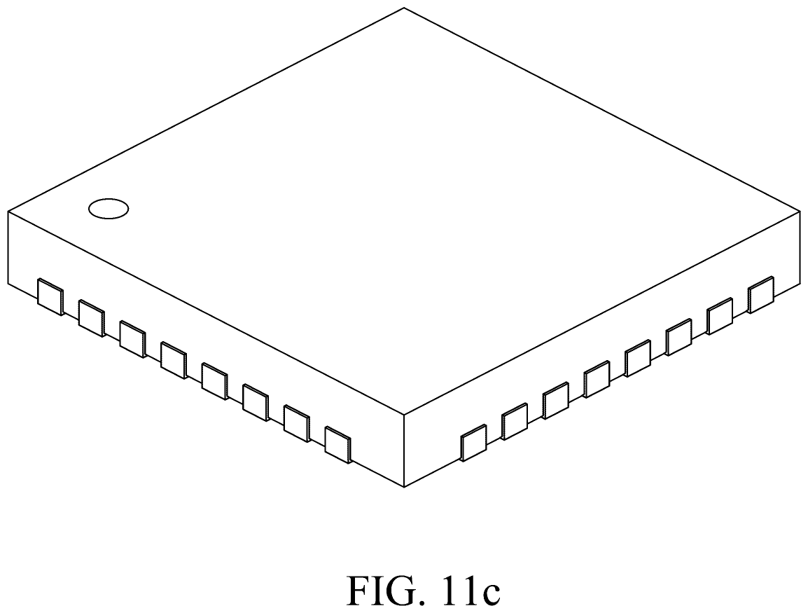

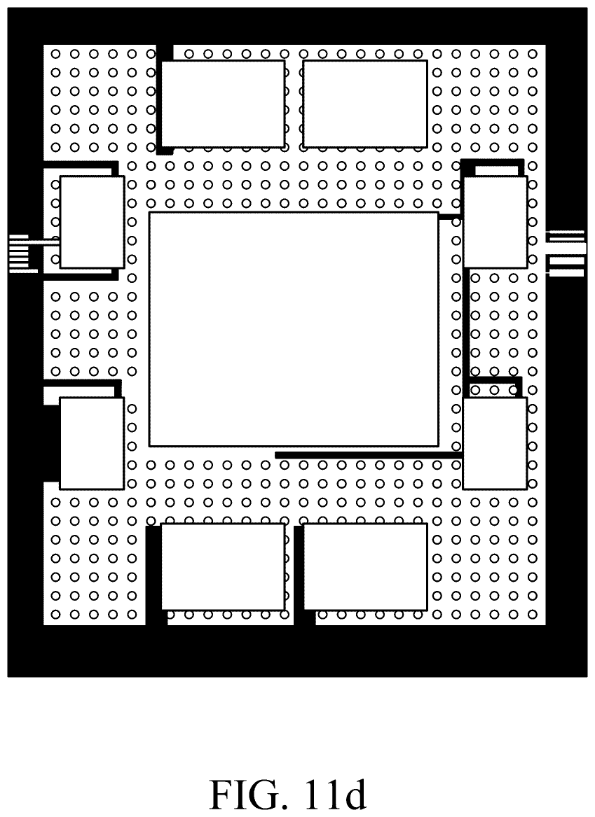

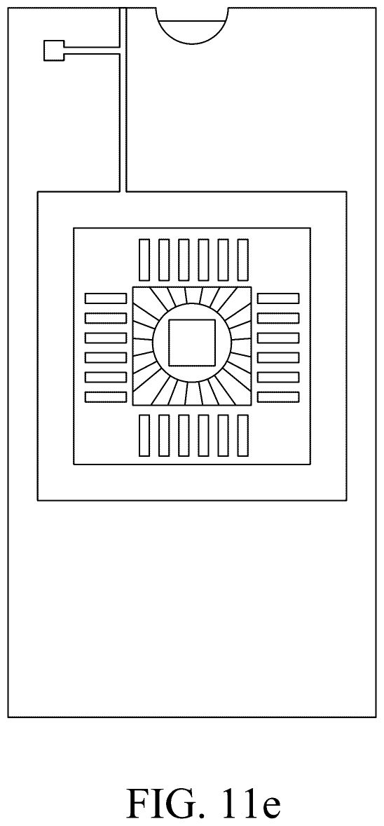

FIGS. 11a-11e illustrate an assortment of thermal test vehicles/carriers, representing various optional embodiments of the present disclosure. The thermal test vehicle may comprise previously described arrangements of thermal test chips, including a single thermal test chip or a stack of thermal test chips, with various means of interconnecting the chips and the wiring substrate. The following variations are shown. FIG. 11a shows: a thermal test chip provided in a flip chip ball grid array (FCBGA) package. FIG. 11b shows a chip on board configuration. FIG. 11c shows a molded package. FIG. 11d shows a multi-chip assembly. FIG. 11e shows a ceramic package. The ceramic package of FIG. 11e may be hermetic when sealed with a lid. In some embodiments, a thermal test vehicle such as described above will be productized together with supporting equipment to form a thermal test set. The supporting equipment may include items such as a heat sink, one or more power supplies, and one or more function testers or test equipment. In this manner, thermal engineers can be provided with a turnkey solution that saves much time and energy, while accelerating time to market of a thermally advanced product.

Any of the vehicles/carriers shown in FIGS. 11a-11e can be used to host any of the different thermal test chip assemblies disclosed herein, or any combination of the thermal test chip assemblies disclosed herein.

In embodiments described herein, a printed wiring board and a substrate can be used interchangeably, and can be of different materials, such as organic, silicon, ceramic or glass, with electrical circuitry disposed therein. Such substrates or boards can be rigid or flexible. The choice of the printed wiring board or a substrate of a particular material or configuration depends on the actual semiconductor devices that these thermal test chips are meant to emulate in a particular application.

As will be understood by those familiar with the art, the invention may be embodied in other specific forms without departing from the spirit or essential characteristics thereof. Likewise, the particular naming and division of the members, features, attributes, and other aspects are not mandatory or necessarily significant, and the mechanisms that implement the invention or its features may have different structural construct, names, and divisions. Accordingly, the disclosure of the invention is intended to be illustrative, but not limiting, of the scope of the invention.

While the invention has been described in terms of several embodiments, those of ordinary skill in the art will recognize that the invention is not limited to the embodiments described, but can be practiced with modification and alteration. For example, another embodiment may comprise a more complex arrangement of thermal test chips in a thermal test chip assembly. Other embodiments may have different overall sizes and form factors for a unit cell. The description is thus to be regarded as illustrative instead of limiting. There are numerous other variations to different aspects of the invention described above, which in the interest of conciseness have not been provided in detail.

The invention has been described in relation to particular examples, which are intended in all respects to be illustrative rather than restrictive. Those skilled in the art will appreciate that many different combinations will be suitable for practicing the present invention. For example, the teachings relating to interconnection means can be applied in a system having more than one interconnection means, such as a combination including flip chips, TSVs, and wire bonds on any number of the die in the stack. There can be different arrangements for the chips; for example, the large chips can be on top of the smaller chips in the embodiments illustrated in FIGS. 7, 8, 9 and 10. Any of the chips can be functional chips (instead of thermal test chips). As another example, the chip can be upside down in the embodiment illustrated in FIG. 6. As yet another example, “back-to-back” configurations between stacked die may be arranged, using TSV's and RDLs. Further, there can be any number of chips and any number of layers, including multiple vertical stacks of chips with the same or different numbers of chips per vertical stack. Other implementations of the invention will be apparent to those skilled in the art from consideration of the specification and practice of the invention disclosed herein. Various aspects and/or components of the described embodiments may be used singly or in any combination. It is intended that the specification and examples be considered as exemplary only, and not limiting with respect to the scope of the invention.

We claim:

1. A thermal test chip assembly comprising:
a first semiconductor substrate having a first surface, a second surface opposite said first surface, and a first set of integrated circuits formed in and on said second surface of said first semiconductor substrate, said first set of integrated circuits including a first plurality of thermal test circuits;
a second semiconductor substrate having a first surface, a second surface opposite said first surface, and a second set of integrated circuits formed in and on said second surface of said second semiconductor substrate; and
a circuit substrate including a first set of electrical contacts and interconnect circuitry electrically coupling said first set of integrated circuits and said second set of integrated circuits to said first set of electrical contacts.

2. The thermal test chip assembly of claim 1, wherein said second set of integrated circuits includes functional circuitry of an electronic device being emulated.

3. The thermal test chip assembly of claim 1, wherein said second set of integrated circuits includes a second plurality of thermal test circuits.

4. The thermal test chip assembly of claim 1, wherein:
said first semiconductor substrate, said second semiconductor substrate, and said circuit substrate are coupled in a stacked relationship;
said first semiconductor substrate is disposed between said second semiconductor substrate and said circuit substrate; and
said first surface of said first semiconductor substrate faces said circuit substrate.

5. The thermal test chip assembly of claim 4, wherein said first surface of said second semiconductor substrate faces said second surface of said first semiconductor substrate.

6. The thermal test chip assembly of claim 5, wherein:
said second set of integrated circuits includes a plurality of contact pads formed on said second surface of said second semiconductor substrate; and
each contact pad of said contact pads formed on said second surface of said second semiconductor substrate is coupled to said interconnect circuitry of said circuit substrate via a wire.

7. The thermal test chip assembly of claim 5, wherein:
said first semiconductor substrate includes a first set of through silicon vias (TSVs);
said second semiconductor substrate includes a second set of TSVs;
said first set of integrated circuits is coupled to said interconnect circuitry of said circuit substrate by some TSVs of said first set of TSVs; and
said second set of integrated circuits is coupled to said interconnect circuitry of said circuit substrate by said second set of TSVs and other TSVs of said first set of said TSVs.

8. The thermal test chip assembly of claim 1, wherein:
said first semiconductor substrate, said second semiconductor substrate, and said circuit substrate are coupled in a stacked relationship;
said first semiconductor substrate is disposed between said second semiconductor substrate and said circuit substrate; and
said second surface of said first semiconductor substrate faces said second surface of said second semiconductor substrate.

9. The thermal test chip assembly of claim 8, further comprising an interconnect layer disposed between said first semiconductor substrate and said second semiconductor substrate, said interconnect layer electrically coupling said second set of integrated circuits to said interconnect circuitry of said circuit substrate.

10. The thermal test chip assembly of claim 8, wherein:
said first semiconductor substrate includes a first set of TSVs and a second set of TSVs;
said first set of integrated circuits is electrically coupled to said interconnect circuitry of said circuit substrate by said first set of TSVs; and
said second set of integrated circuits is electrically coupled to said interconnect circuitry of said circuit substrate by said second set of TSVs.

11. The thermal test chip assembly of claim 1, wherein:
said first semiconductor substrate, said second semiconductor substrate, and said circuit substrate are coupled in a stacked relationship;
said first semiconductor substrate is disposed between said second semiconductor substrate and said circuit substrate; and
said second surface of said first semiconductor substrate faces said circuit substrate.

12. The thermal test chip assembly of claim 11, wherein:
said first set of semiconductor circuits includes a second set of electrical contacts; and
contacts of said second set of electrical contacts are electrically coupled to interconnect circuitry of said circuit substrate.

13. The thermal test chip assembly of claim 12, wherein contacts of said second set of electrical contacts are directly bonded to said interconnect circuitry of said circuit substrate.

14. The thermal test chip assembly of claim 12, further comprising an interconnect layer disposed between said first semiconductor substrate and said circuit substrate, said interconnect layer electrically coupling said second set of contacts to said interconnect circuitry of said circuit substrate.

15. The thermal test chip assembly of claim 11, wherein:
said second surface of said second semiconductor substrate faces said first surface of said first semiconductor substrate;
said first semiconductor substrate includes a first set of TSVs; and
said first set of integrated circuits is electrically coupled to said second set of integrated circuits by said first set of TSVs.

16. The thermal test chip assembly of claim 1, further comprising:
a third semiconductor substrate having a first surface, a second surface opposite said first surface, and a third set of integrated circuits formed in and on said second surface of said third semiconductor substrate, said third set of integrated circuits being electrically coupled to said interconnect circuitry of said circuit substrate; and wherein
said second set of integrated circuits includes a second plurality of thermal test circuits.

17. The thermal test assembly of claim 16, wherein:
said first semiconductor substrate is disposed between said circuit substrate and said second semiconductor substrate; and
said first semiconductor substrate is disposed between said circuit substrate and said third semiconductor substrate.

18. The thermal test assembly of claim 17, wherein said second semiconductor substrate is disposed between said first semiconductor substrate and said third semiconductor substrate.

19. The thermal test assembly of claim 17, wherein:
said second semiconductor substrate is disposed over a first area of said first semiconductor substrate;
said third semiconductor substrate is disposed over a second area of said first semiconductor substrate; and
said first area is spaced apart from said second area.

20. The thermal test chip assembly of claim 19, wherein said third set of integrated circuits includes functional circuitry of an electronic device being emulated.

21. The thermal test chip assembly of claim 19, wherein said third set of integrated circuits includes a third plurality of thermal test circuits.

22. The thermal test chip assembly of claim 19, wherein:
said first surface of said first semiconductor substrate faces said circuit substrate;
said second surface of said second semiconductor substrate faces said second surface of said first semiconductor substrate; and
said second surface of said third semiconductor substrate faces said second surface of said first semiconductor substrate.

23. The thermal test chip assembly of claim 22, wherein:
said first semiconductor device includes a first set of TSVs, a second set of TSVs, and a third set of TSV;
said first set of said integrated circuits is electrically connected to said interconnect circuitry of said circuit substrate by said first set of TSVs;
said second set of integrated circuits is electrically connected to said interconnect circuitry of said circuit substrate by said second set of TSVs; and
said third set of integrated circuits is electrically connected to said interconnect circuitry of said circuit substrate by said third set of TSVs.

24. The thermal test chip assembly of claim 23, further comprising:
a first interconnect layer disposed between said first semiconductor substrate and said second semiconductor substrate, said first interconnect layer electrically connecting said second set of integrated circuits to said second set of TSVs; and
a second interconnect layer disposed between said first semiconductor substrate and said third semiconductor substrate, said second interconnect layer electrically connecting said third set of integrated circuits to said third set of TSVs.

25. The thermal test chip assembly of claim 19, wherein a space between said second semiconductor substrate and said third semiconductor substrate is occupied by a fill material.

26. The thermal test chip assembly of claim 25, wherein said fill material includes at least one of a molding compound and an oxide.

27. The thermal test chip assembly of claim 19, further comprising a fluid conduit disposed at least partially in a space between said second semiconductor substrate and said third semiconductor substrate for containing a cooling fluid.

28. The thermal test chip assembly of claim 1, further comprising:
a third semiconductor substrate having a first surface and a second surface opposite said first surface; and wherein
said third semiconductor substrate is mechanically coupled to said first semiconductor substrate and said second semiconductor substrate;
there are no electrical connections between said first set of integrated circuits and any integrated circuits of said third semiconductor substrate; and
there are no electrical connections between said second set of integrated circuits and any integrated circuits of said third semiconductor substrate.

29. The thermal test chip assembly of claim 28, wherein said third semiconductor substrate is a dummy chip with no operational circuits.

30. A thermal test chip comprising:
a semiconductor substrate having a first surface, a second surface opposite said first surface, and an array of thermal test circuits formed in an on said second surface; and wherein
said semiconductor substrate has a first thickness defined as a shortest distance between said first surface and said second surface in a first region of said semiconductor substrate;
said semiconductor substrate has a second thickness defined as a shortest distance between said first surface and said second surface in a second region of said semiconductor substrate; and
said first thickness is greater than said second thickness.

31. The thermal test chip of claim 30, further comprising a cooling fluid in thermal contact with said first surface of said second region.

32. A method of fabricating a thermal test chip, said method including:
providing a semiconductor substrate having a first surface and a second surface opposite said first surface;
forming an array of thermal test circuits in and on said second surface of said semiconductor substrate;
removing material from a predefined region of said first surface of said semiconductor substrate, whereby a first thickness of said semiconductor substrate in said predefined region of said first surface is less than a second thickness of said semiconductor substrate in a second region outside of said predefined region.
